(19) United States
(12) Patent Application Publication
(10) Pub. No.: US 2025/0056813 A1
(43) Pub. Date: Feb. 13, 2025

(54) SEMICONDUCTOR CHIP AND SEMICONDUCTOR PACKAGE INCLUDING THE SEMICONDUCTOR CHIP

(71) Applicant: SAMSUNG ELECTRONICS CO., LTD., SUWON-SI (KR)

(72) Inventor: Seulji Song, Suwon-si (KR)

(21) Appl. No.: 18/781,103

(22) Filed: Jul. 23, 2024

(30) Foreign Application Priority Data
Aug. 7, 2023 (KR) 10-2023-0102907

(51) Int. Cl. H10B 63/10; G06N 3/063; G11C 11/418; G11C 11/419; G11C 13/00; H01L 23/498; H01L 23/528; H01L 23/532; H01L 27/02; H10B 10/00; H10B 80/00

(52) U.S. Cl. CPC H10B 63/10; G06N 3/063; H01L 23/528; H01L 27/0207; G11C 11/418; G11C 11/419; G11C 13/0004; H01L 23/49822; H01L 23/53209; H10B 10/00; H10B 80/00

(57) ABSTRACT

A semiconductor chip includes a logic core layer that receives input data from an external host and calculates an inference value based on the input data, a redistribution wiring layer provided on the logic core layer, wherein the redistribution wiring layer includes a plurality of redistribution wirings, which transmit the input data, and an insulating layer, which covers the plurality of redistribution wirings, and a weight storage layer provided on the redistribution wiring layer, wherein the weight storage layer includes a plurality of memory cells, each of which store weights for calculating the inference value through amorphous materials, wherein the weights are transmitted to the logic core layer through the plurality of redistribution wirings according to the input data.

### CROSS-REFERENCE TO RELATED APPLICATIONS

This application claims priority under 35 U.S.C. § 119 to Korean Patent Application No. 10-2023-0102907, filed on Aug. 7, 2023 in the Korean Intellectual Property Office (KIPO), the contents of which are herein incorporated by reference in their entirety.

### BACKGROUND

### 1. Field

Embodiments relate to a semiconductor chip and a semiconductor package including the semiconductor chip. More particularly, example embodiments relate to a semiconductor chip configured to perform neuromorphic computing and a semiconductor package including the same.

### 2. Description of the Related Art

Artificial neural network (ANN) technology can be used for machine learning, such as artificial intelligence (AI). In order to increase the accuracy of data learned in artificial neural network technology, there is a desire to repeatedly update weights through feedback. Energy efficiency may decrease during the process of repeatedly updating weights.

Accordingly, a selector only memory (SOM) device is used as a memory for synaptic storage in an artificial neural network technology that implements an inference algorithm, to minimize the number of weight updates, and to minimize the physical movement distance of data through monolithic integration with the computing logic unit thereby increasing energy efficiency.

### SUMMARY

Example embodiments provide a semiconductor chip with an optimized structure to increase energy efficiency in artificial neural network technology.

Example embodiments provide a semiconductor package including the semiconductor chip.

According to example embodiments, a semiconductor chip includes a logic core layer configured to receive input data and calculate an inference value based on the input data, a redistribution wiring layer provided on the logic core layer, wherein the redistribution wiring layer includes a plurality of redistribution wirings, which are configured to transmit the input data, and an insulating layer, which covers the plurality of redistribution wirings, and a weight storage layer provided on the redistribution wiring layer, wherein the weight storage layer includes a plurality of memory cells that are configured for storing weights for calculating the inference value, wherein the weights are transmitted to the logic core layer through the plurality of redistribution wirings according to the input data.

According to example embodiments, a semiconductor chip includes a logic core layer configured to receive input data, and calculate an inference value based on the input data and weights, a redistribution wiring layer bonded to a surface of the logic core layer, wherein the redistribution wiring layer includes a plurality of redistribution wirings, which are configured to transmit the input data and the weights, and an insulating layer, which covers the plurality of redistribution wirings, and a weight storage layer on the redistribution wiring layer, wherein the weight storage layer includes memory cells configured to respectively store the weights through amorphous materials, wherein the weight storage layer is configured to receive the input data through the plurality of redistribution wirings, and transfer at least portions of the weights to the logic core layer through the plurality of redistribution wirings in response to the input data.

According to example embodiments, a semiconductor package includes a package substrate, and a semiconductor chip disposed on the package substrate. The semiconductor chip includes a logic core layer configured to receive input data through the package substrate, and calculate an inference value based on the input data and weights, a redistribution wiring layer on the logic core layer, wherein the redistribution wiring layer includes a plurality of redistribution wirings, which are configured to transmit the input data and the weights, and an insulating layer, which covers the plurality of redistribution wirings, and a weight storage layer provided on the redistribution wiring layer, wherein the weight storage layer includes memory cells configured to respectively store the weights through amorphous materials, wherein the weight storage layer is configured to receive the input data through the plurality of redistribution wirings, and transfer at least portions of the weights to the logic core layer through the plurality of redistribution wirings in response to the input data.

According to example embodiments, a semiconductor chip may include a logic core layer that receives input data from an external host and calculates an inference value based on the input data, a plurality of redistribution wiring layer provided on the logic core layer, and including a plurality of redistribution wirings, which are for transmitting the input data, and an insulating layer, which covers the plurality of redistribution wirings, and a weight storage layer provided on the redistribution wiring layer, and including a plurality of memory cells storing weights for calculating the inference value through amorphous materials. The weight storage layer transfers the weights to the logic core layer through the plurality of redistribution wirings.

Accordingly, the weight storage layer may perform artificial neural network (ANN) technology through the plurality of memory cells. The weight storage layer may store the weights through the plurality of memory cells. The weight storage layer and the logic core layer may be electrically connected to each other through the redistribution wirings of the redistribution wiring layer. The weight storage layer and the logic core layer may have a monolithic structure through the redistribution wiring layer. Because the weight storage layer and the logic core layer are electrically connected to each other through the redistribution wiring layer, the logic core layer may receive the weights that are stored in the plurality of memory cells of the weight storage layer by using less energy.

Further, the weights may not require repeated learning through feedback, and the weight storage layer may have an optimization structure for obtaining the inference value. The weight storage layer and the logic core layer may be optimized for inference to obtain the inference value and may have high energy efficiency.

### BRIEF DESCRIPTION OF THE DRAWINGS

Example embodiments will be more clearly understood from the following detailed description taken in conjunction with the accompanying drawings.

FIGS. 1 to 5 represent non-limiting, example embodiments as described herein.

FIG. 1 is a block diagram illustrating a semiconductor package in accordance with example embodiments.

FIG. 2A is a block diagram illustrating a semiconductor chip in accordance with example embodiments.

FIG. 2B is a block diagram illustrating a weight storage layer on the logic core layer of the semiconductor chip in FIG. 2A.

FIG. 3 is a front view illustrating the semiconductor package of FIG. 1.

FIG. 4 is a cross-sectional view taken along the line A-A′ in FIG. 3.

FIG. 5 is a diagram illustrating how a memory cell stores weights.

### DETAILED DESCRIPTIONS

Principles and embodiments of the present disclosure relate to using amorphous material for storing weights for an artificial neural network (ANN). If non-volatile memory with higher write power than read power, such as selector only memory (SOM), is used as a synapse, there is a problem that energy consumption may increase during the learning process and a size of the model that can be computed at one time may be limited.

Hereinafter, example embodiments will be explained in detail with reference to the accompanying drawings.

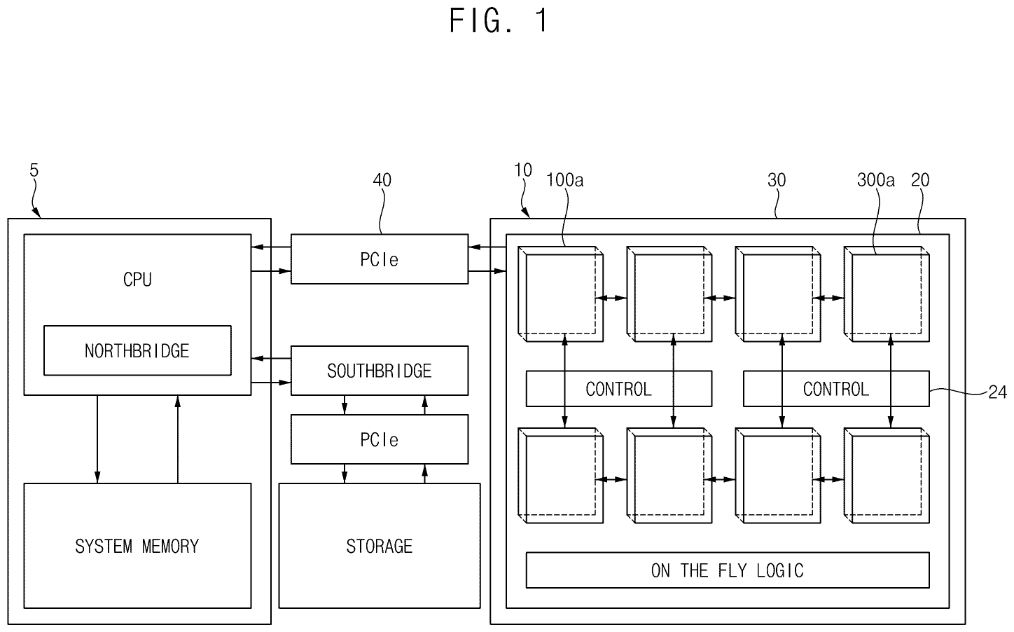

FIG. 1 is a block diagram illustrating a semiconductor package in accordance with example embodiments.

Referring to FIG. 1, a computing system may include a semiconductor package 10 having at least one semiconductor chip 20 and a host 5 electrically connected to the semiconductor package 10 through an interface 40. For example, the computing system may include a personal laptop computer, a desktop computer, a digital camera, a mobile phone, a memory card reader, or an Internet of Things (IoT) enabled device.

In various embodiments, the host 5 may include processing resources capable of accessing memory. The processing resources may include at least one processor, microprocessor, etc. The computing system may include discrete integrated circuits. Alternatively, the computing system may have the host and the semiconductor chip 20 on the same integrated circuit. For example, the host may be a system controller of a memory system including a plurality of semiconductor chips 20. In this case, the system controller may provide access to each of the plurality of semiconductor chips 20 through a central processing unit (CPU). The host may include an AI chip configured for AI processing.

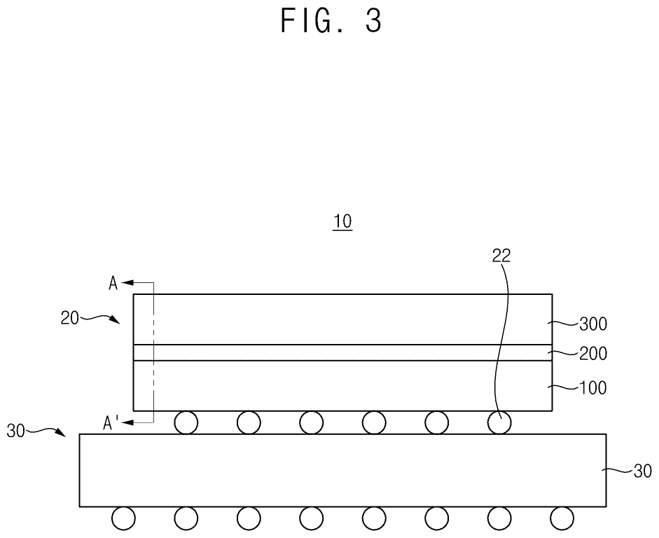

In various embodiments, the semiconductor package 10 may include a semiconductor chip 20 mounted on a package substrate 30, as shown in FIG. 3. The semiconductor chip 20 may have a neural processing unit (NPU) array structure. The neural processing unit array structure may include a plurality of local logic cores 100a as logic operation units and a plurality of local weight storages 300a as weight storage units. The semiconductor chip 20 may have a monolithic structure. The monolithic structure may include a monolithic integrated circuit.

The semiconductor chip 20 may include a control unit 24. The control unit 24 may include a high voltage circuit. The high voltage circuit can perform addressing, re-programming, read operations, etc. on a core layer.

The neural processing unit array structure can transmit/receive data through the interface 40, which may be, for example, a serial bus, an off-chip interconnect interface, etc. For example, the neural processing unit array structure may receive initial input data via a universal serial bus. The neural processing unit array structure may transmit the data to the system through a main buffer.

The logic operation unit 100a and the weight storage unit 300a may be electrically connected to each other through the monolithic structure. The monolithic structure may have a structure in which the logic operation unit 100a and the weight storage unit 300a are provided as a single device. The logic operation unit 100a can efficiently receive data from the weight storage unit 300a through the monolithic structure.

For example, the semiconductor chip 20 can perform artificial neural network (ANN) technology for machine learning such as artificial intelligence (AI).

The semiconductor package 10 may further include the package substrate 30 on which the semiconductor chip 20 is mounted. The package substrate 30 may be a substrate having an upper surface and a lower surface opposite to the upper surface. For example, the package substrate 30 may be a printed circuit board (PCB). The printed circuit board may be a multilayer circuit board having vias and various circuits therein.

The semiconductor chip 20 may be placed on the package substrate 30. A planar area of the semiconductor chip 20 may be smaller than a planar area of the package substrate 30. When viewed in a plan view, the semiconductor chip 20 may be disposed within an area of the package substrate 30. The semiconductor chip 20 may be mounted on the package substrate 30 via conductive bumps 22. Alternatively, the semiconductor chip 20 may be electrically connected to the package substrate 30 through conductive wires.

Since the semiconductor chip 20 has the logic operation unit and the weight storage unit through the monolithic structure, the semiconductor package 10 may not have a memory storage device such as a high bandwidth memory (HBM) device on the package substrate 30. Since the semiconductor package 10 does not include the memory storage device, the area of the semiconductor package 10 can be small. The semiconductor package 10 may not be provided with an interposer to electrically connect the semiconductor chip 20 and the memory storage device. Because the area of the semiconductor package 10 is small and does not include the interposer, the semiconductor package 10 can be miniaturized.

Hereinafter, the semiconductor chip will be described in more detail.

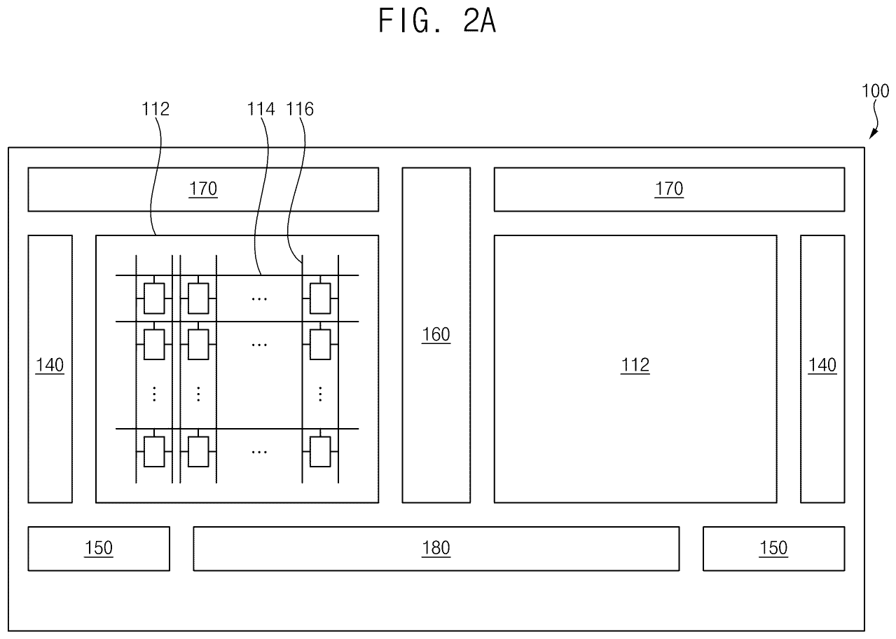

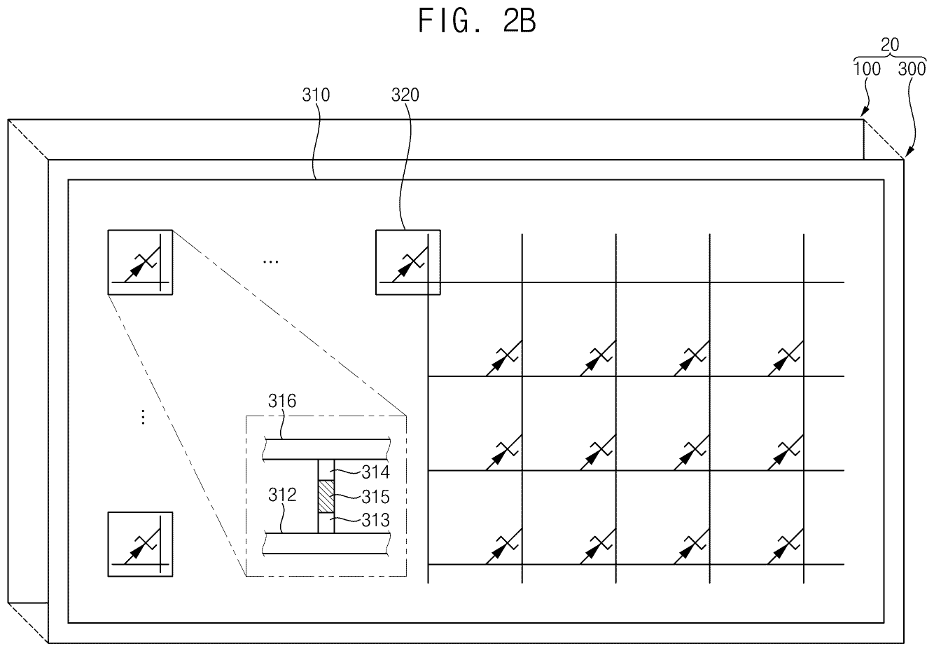

FIG. 2A is a block diagram illustrating a logic core layer of a semiconductor chip in accordance with example embodiments. FIG. 2B is a block diagram illustrating a weight storage layer on the logic core layer of the semiconductor chip in FIG. 2A.

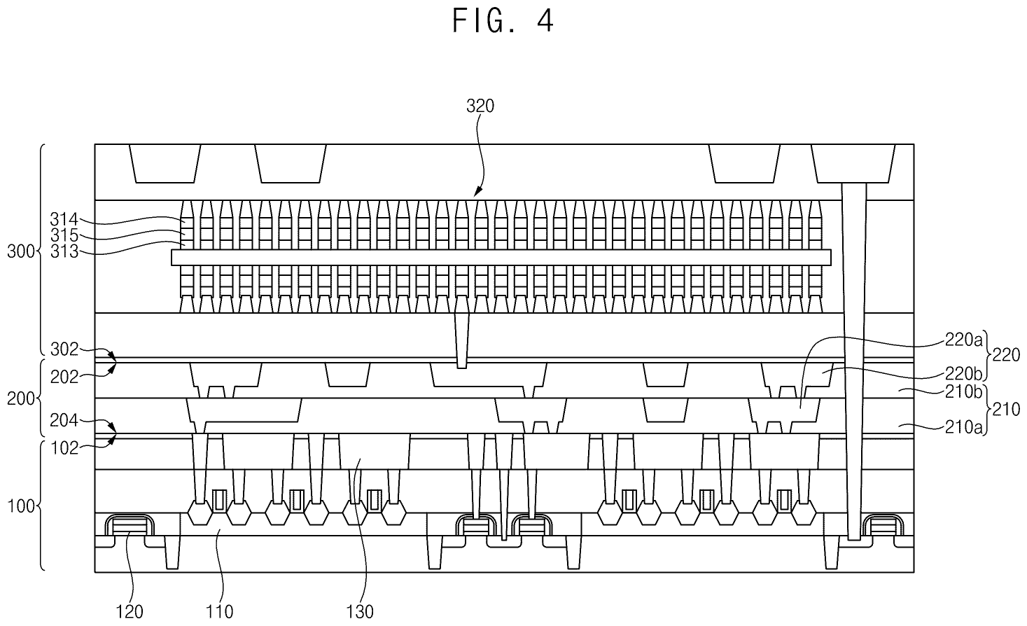

FIG. 3 is a front view illustrating the semiconductor package of FIG. 1. FIG. 4 is a cross-sectional view taken along the line A-A′ in FIG. 3.

Referring to FIGS. 1 to 4, the semiconductor chip 20 may include a logic core layer 100, a redistribution wiring layer 200 provided on the logic core layer 100, and a weight storage layer 300 provided on the redistribution wiring layer 200 and having a memory array 310 for storing weights. The logic core layer 100 may include the plurality of local logic cores 100a, and the weight storage layer 300 may include the plurality of weight storages 300a.

The semiconductor chip 20 may have a structure for performing neuromorphic computing. The neuromorphic computing structure may have circuits that mimic the shape of human neurons. The neuromorphic computing structure may have circuitry for simulating human brain function. The semiconductor chip 20 may store the weights through the local weight storage 300a and perform an operation based on the weights through the local logic core 100a to perform the neuromorphic computing.

In various embodiments, the local logic core 100a may receive input data from the host 5. The local logic core 100a may be electrically connected to the host 5 through the package substrate 30. The local logic core 100a may calculate an inference value based on the input data and the weights. The local logic core 100a may update the weights of the local weight storage 300a based on the input data. For example, the inference value may be a result value that is calculated from the local logic core 100 based on the weights.

The logic core layer 100 may include an activation layer 110 having a circuit layer therein, as shown in FIG. 4. The circuit layer may include a plurality of circuit patterns 120 therein. The plurality of circuit patterns 120 may include transistors, diodes, etc. The plurality of circuit patterns 120 may be formed by a wafer process called front-end-of-line (FEOL).

The activation layer 110 may vary depending on the type of semiconductor chip 20. For example, the activation layer 110 includes SRAM (Static Random Access Memory), DRAM (dynamic random access memory), NAND Flash Memory, or Silicon Carbide Circuit (SiC Circuit). The activation layer 110 may include an application processor (AP).

The logic core layer 100 may include a plurality of connection pads 130 that are electrically connected to the plurality of circuit patterns 120, as shown in FIG. 4. The logic core layer 100 may be electrically connected to the redistribution wiring layer 200 through the plurality of connection pads 130.

For example, the logic core layer 100 may include a logic processing unit that is configured to calculate an inference value based on the input data and the weight. The logic processing unit may include a cell (SRAM) array 112, a first word line decoder (first row decoder for SRAM) 140, and a first bit line decoder (first column decoder for SRAM) & a first sense amplifier (first sense amplifier array for SRAM) 150. The logic core layer 100 may further include a memory decoder. The memory decoder may include a second word line decoder (second row decoder for SOM) 160, a second bit line decoder (second column decoder for SOM) 170, and a second sense amplifier for SOM 180, as shown in FIG. 2A.

The first row decoder for SRAM 140 may be connected to a word line 114 of the SRAM array 112. The first column decoder & the first sense amplifier array for SRAM 150 may be connected to a bit line 116 of the SRAM array 112. When the data in the bit line is a low-power signal, the first sense amplifier for SRAM 150 may amplify the data to a logic level.

For example, the SRAM array 112 may perform a multiplication operation to compare similarity between input data and a weight value (reference data). The first row decoder for SRAM 140 may receive the input data from the host. The first column decoder & the first sense amplifier array for SRAM 150 may receive the weight value (the reference data) from the second sense amplifier for SOM 180, and may output result of the calculation from the SRAM array 112.

The plurality of circuit patterns 120 of the logic core layer 100 may include an address circuit that matches an address signal provided through the interface 40 and a control circuit that decodes the input data provided from the host. The plurality of circuit patterns 120 of the logic core layer 100 may further include an I/O circuit and a read/write circuit.

The interface 40 may include a physical interface employing an appropriate protocol. The interface 40 may include standard protocols. For example, the physical interface may include a data bus, an address bus, a command bus, etc. The standard protocol may include Peripheral Component Interconnect Express (PCIe), Gen-Z, cache coherent interconnect for accelerator (CCIX), etc.

The address circuit may match the address signal provided from the host 5 through the interface 40. The address signal may be transmitted to the weight storage layer 300 and decoded in the weight storage layer 300 to access the memory array 310.

The control circuit may decode the input signal received from the host 5. The input signal may be a command provided by the host 5. The host 5 may be a controller that is external to the semiconductor chip 20. For example, the host 5 may be a memory controller coupled to the processing resources of a computing device. The input signal may include a control signal for controlling the operation performed on the memory array 310. For example, performing the operation may include a data read operation, a data write operation, a data erase operation, etc. The control signal may include a chip activation signal, a write activation signal, and an address latch signal.

The I/O circuit may perform two-way data communication with the host 5 through the interface 40.

The read/write circuit may input data into the memory array 310 and read data from the memory array 310. For example, the read/write circuit may include various drivers, latch circuits, etc.

In example embodiments, the redistribution wiring layer 200 may be provided between the logic core layer 100 and the weight storage layer 300. The redistribution wiring layer 200 may have a first surface 202 and a second surface 204 that is opposite to the first surface 202.

The semiconductor chip 20 may have a cell on peri (COP) structure through the redistribution wiring layer 200. The cell-on-peri structure may have a peri that controls a memory semiconductor, and a storage space cell provided on the peri. The redistribution wiring layer 200 may be provided between the logic core layer 100 and the weight storage layer 300 to form the cell-on-peri structure. For example, the logic core layer 100 may be the peri and the weight storage layer 300 may be the storage space cell.

In example embodiments, the redistribution wiring layer 200 may include a plurality of insulating layers 210 and redistribution wirings 220 provided in the plurality of insulating layers 210. The redistribution wirings 220 may include first and second redistribution wirings 220a and 220b.

The insulating layers 210 may include polymer, dielectric layer, etc. The insulating layers 210 may be formed by a vapor deposition process, a spin coating process, etc. The redistribution wirings 220 may be formed by a plating process, an electroless plating process, a vapor deposition process, etc. For example, the redistribution wirings 220 may include copper (Cu), aluminum (Al), tungsten (W), nickel (Ni), molybdenum (Mo), gold (Au), silver (Ag), chromium (Cr), tin (Sn), titanium (Ti), or an alloy thereof.

The first redistribution wirings 220a may be provided in a first insulating layer 210a, and the second redistribution wirings 220b may be provided in a second insulating layer 210b. In particular, lower surfaces of the first redistribution wirings 220a may be exposed from a lower surface of the first insulating layer 210a. The first insulating layer 210a may have first openings that expose the lower surfaces of the first redistribution wirings 220a.

The first redistribution wirings 220a may be formed in the first insulating layer 210a and may contact the connection pads 130 of the logic core layer 100 through the first openings. The second insulating layer 210b may be formed on the first insulating layer 210a and may have second openings that expose the second redistribution wirings 220b. The second redistribution wirings 220b may be formed on the first insulating layer 210a and may contact the first redistribution wirings 220a through the second openings of the second redistribution wirings 220b. At least portions of the second redistribution wirings 220b may be exposed from an upper surface of the second insulating layer 210b.

The weight storage layer 300 may be provided on the first surface 202 of the redistribution wiring layer 200. The logic core layer 100 may be provided on the second surface 204 of the redistribution wiring layer 200. The redistribution wiring layer 200 may electrically connect the logic core layer 100 and the weight storage layer 300 to each other through the redistribution wirings 220.

The first insulating layer 210a of the redistribution wiring layer 200 may be bonded to the upper surface 102 of the logic core layer 100. The second insulating layer 210b of the redistribution wiring layer 200 may be bonded to the lower surface 302 of the weight storage layer 300. Accordingly, the redistribution wiring layer 200 may be directly bonded to the logic core layer 100 and the weight storage layer 300, and the logic core layer 100 and the weight storage layer 300 may have the monolithic structure and may be electrically connected to each other through the redistribution wiring layer 200.

The redistribution wiring layer 200 may transmit data through the redistribution wirings 220. The data may include the input data and the weights.

Because the logic core layer 100 and the weight storage layer 300 are electrically connected to each other in the monolithic structure, the data may move between the logic core layer 100 and the weight storage layer 300 using little energy. For example, the energy generated in data movement between the logic core layer 100 and the weight storage layer 300 may be in a range of about 1 Pj/bit to about 3 Pj/bit.

In example embodiments, the weight storage layer 300 may include a memory array 310 for storing the weights.

The memory array 310 may include a plurality of memory cells 320, each of which may be storing a weight. The weight storage layer 300 may be provided on the redistribution wiring layer 200.

For example, the weight storage layer 300 may include selector only memory (SOM). The selector only memory may be a device that implements a memory and a selector as a single device. The single selection device memory may use amorphous materials to store the weights.

The selector only memory may have an intersection structure disposed between orthogonal conductive lines. The intersection structure may be a structure in which a memory cell is located at a contact point of orthogonal first and second conductive line patterns. The intersection structure may include a 2-terminal memory device.

The selector only memory may include a selection element. The selection element may be provided on the intersection structure. The selection element may prevent interference caused by sneak current between adjacent cells among the plurality of memory cells 320. For example, the selection elements may include diodes, transistors, threshold switches, etc. The selector only memory may simultaneously perform memory and selector functions through one material. The selector only memory may implement a highly integrated memory in a vertical direction.

The second bit line decoder for SOM 170 and the second word line decoder for SOM 160 may be connected to the memory cells 320 in the weight storage layer 300. The second bit line decoder for SOM 170 and the second word line decoder for SOM 160 may decode the weights within the memory cells 320. The second sense amplifier for SOM 180 may amplify the weights in the memory cells 320 when the weights are low-power signals. The second sense amplifier for SOM 180 may transfer the reference data (weight value) stored in the memory array 310, to the first column decoder & the first sense amplifier array for SRAM 150.

The cell (SRAM) array 112, the first row decoder for SRAM 140 and the first column decoder & the first sense amplifier array for SRAM 150 of the logic core layer 100 may be arranged to have a symmetrical shape together with the second bit line decoder for SOM 170, the second word line decoder for SOM 160, and the second sense amplifier for SOM 180 for the weight storage layer 300. In this case, the second word line decoder for SOM 160 may be provided in the center of the symmetrical structure. The logic core layer 100 and the weight storage layer 300 may reduce area efficiency and asymmetry in data movement distance through the symmetrical shape.

The weight storage layer 300 may store the weights through the plurality of memory cells 320. The weight storage layer 300 may repeatedly transmit pre-stored weights to the logic core layer 100. The weight storage layer 300 may use the pre-stored weights in response to the input data of the logic core layer 100. In the weight storage layer 300, the weights may be stored the first time. Because the weights are stored in the weight storage layer 300 the first time, the semiconductor chip 20 may reduce energy consumption for storing the weights in the weight storage layer 300.

Because the weight storage layer 300 repeatedly uses the pre-stored weights, the logic core layer 100 may reduce energy consumption for updating the weight storage layer 300. Because the weight storage layer 300 repeatedly uses the pre-stored weights, the logic core layer 100 may be optimized for inference (reference). Accordingly, the semiconductor chip 20 may calculate the inference value using less energy.

Alternatively, the weights of the weight storage layer 300 may be updated through an iterative learning process. The weights of the weight storage layer 300 may be updated by the input data of the logic core layer 100.

The weight storage layer 300 may be formed on the redistribution wiring layer 200 during a low-temperature manufacturing process. Since the weight storage layer 300 is formed during the low-temperature manufacturing process, the thermal burden on the logic core layer 100 may be reduced during the manufacturing process. Since the weight storage layer 300 is formed during the low-temperature manufacturing process, the monolithic structure may be formed between the weight storage layer 300 and the logic core layer 100. For example, the low-temperature manufacturing process may be performed at about 400 degrees or less.

The weight storage layer 300 may receive the input data from the logic core layer 100 through the plurality of redistribution wirings 220. The weight storage layer 300 may transmit at least portions of the weights to the logic core layer 100 through the plurality of redistribution wirings 220 according to the input data.

The weight storage layer 300 may receive the address signal from the logic core layer 100 through the redistribution wirings 220. The address signal may be received by the memory decoder including the second bit line decoder for SOM 170 and the second word line decoder for SOM 160r. The address signal may be received and decoded by the row decoder and the column decoder and access the memory array 310.

The memory array 310 may have a sensing circuit. The sensing circuit may sense changes in voltage or current on a sense line 316, and the weights may be read from the memory array 310 via the sensing circuit. For example, the sensing circuit may include a sense amplifier capable of reading and matching pages (e.g., rows or columns) of data from the memory array 310.

The memory array 310 may have a neuromorphic computing architecture. The neuromorphic computing architecture may be implemented using the plurality of memory cells 320. The plurality of memory cells 320 may include a single selection device memory cell. For example, the single selection element memory cell may be a memory unit including a single chalcogenide material to act as a selection element or a storage element.

When the memory array 310 is accessed, the memory cells 320 may be read or sensed by the sensing circuit to determine their programming state. For example, a voltage may be applied to each of the memory cells 320 via an access line 312 or the sense line 316, and the presence of a resulting current for each of the memory cells 320 may vary depending on the applied voltage and the threshold voltage of each of the memory cells 320. The logic state of each of the memory cells 320 may be determined by evaluating the voltage that results in current flow.

The memory cells 320 may further include transistors to perform an artificial synapse function. For example, the transistors may include a field-effect transistor (FET). The transistors may include a three terminal device including a source, a drain and a gate.

The memory cells 320 may store the weights through the amorphous materials respectively. The semiconductor chip 20 may include a memory unit configured to store the weights through the plurality of memory cells 320. For example, the memory unit may include a neural memory unit.

The memory controller of a host may be coupled to the neural memory unit. The memory controller and the neural memory unit may constitute a neural memory unit controller.

The neural memory unit may be configured to mimic neuro-physiological architecture. The neural memory unit may change the properties of the amorphous material within the memory cell 320. For example, the amorphous material may include the chalcogenide material. The properties of the chalcogenide material may be changed, and the changed properties can change the threshold voltage of the memory cell 320. The threshold voltage of the neural memory of the neural memory unit may be interpreted as the weights as a result of learning in the neural memory unit.

The memory cell 320 may include a first electrode 313, an amorphous material 315 and a second electrode 314. For example, the first electrode 313 may be a bottom electrode, and the second electrode 314 may be a top electrode. The amorphous material 315 may be provided between the first electrode 313 and the second electrode 314.

The memory cell 320 may include the access line 312 and the sense line 316. For example, the first electrode 313 may be electrically connected to the access line 312, and the second electrode 314 may be electrically connected to the sensing line 316.

Alternatively, the access line 312 and the sense line 316 may include electrode layers. In this case, the access line 312 and the sensing line 316 may be formed in multiple layers. The electrode layers may be interfaced with the amorphous material 315. For example, the access line 312 and the sense line 316 may be interfaced directly with the amorphous material 315 with or without an electrode layer.

Hereinafter, a method of store the weights in the memory cells will be described in detail.

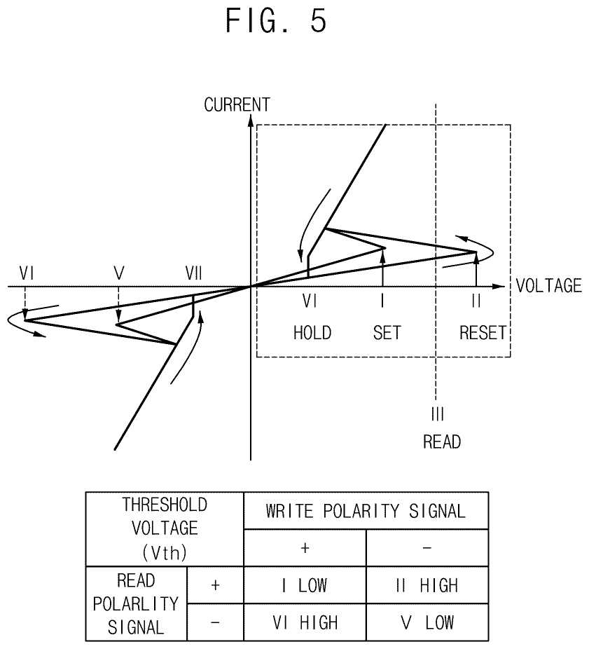

FIG. 5 is a diagram illustrating how a memory cell stores weights.

Referring to FIGS. 1 to 5, the memory cell 320 may be a variable resistance memory cell. The memory cell 320 may change the logic state of the chalcogenide material in an amorphous state in response to the magnitude of the voltage. For example, the chalcogenide material may be in a high or low conductivity state. For example, the chalcogenide material may include sulfur (S), selenium (Se), tellurium (Te), germanium (Ge), arsenic (As), aluminum (Al), antimony (Sb), indium (In), gallium (Ga), tin (Sn), bismuth (Bi), palladium (Pd), cobalt (Co), oxygen (O), silver (Ag), gold (Au), nickel (Ni), platinum (Pt), etc.

When the access line 312 and the sense line 316 are activated or selected, read and write operations may be performed on the memory cell 320. Activating or selecting the access line 312 or the sense line 316 may include applying a voltage to the respective line. For example, the access line 312 and the sensing line 316 may include copper (Cu), aluminum (Al), gold (Au), tungsten (W), titanium (Ti), etc.

By activating the access line 312, an electrical connection or closed circuit may be established between the logic storage device of the memory cell 320 and its corresponding sense line 316. The sense line 316 may be accessed to read or write the memory cell 320. When the memory cell 320 is selected, the resulting signal may be used to determine the stored logic state. The chalcogenide material of the memory cell 320 may be maintained in an amorphous state during an access operation.

When various types of programming pulses are applied to the memory cell 320, a specific threshold voltage of the memory cell 320 may be determined. The threshold voltage of memory cell 320 may be modified by changing the shape of the programming pulse.

When a read pulse is applied to the memory cell 320, a specific threshold voltage of the memory cell 320 may be determined. For example, when the applied voltage of the read pulse exceeds a certain threshold voltage of the memory cell 320, a finite amount of current may flow through the memory cell 320. When the applied voltage of the read pulse is lower than a certain threshold voltage of the memory cell 320, an insignificant amount of current may flow through the memory cell 320.

The memory cell 320 may store the weights through read and write polarity signals. The polarity signals may include a read polarity signal and a write polarity signal. The memory cell 320 may store the weight by changing the voltage within the amorphous material through the read and write polarity signals. The memory cell 320 may store the weights through the match/mismatch between the read polarity signal and the write polarity signal.

For example, when directions of the read polarity signal and the write polarity signal are the same, the memory cell 320 may have a high voltage value. When the directions of the read polarity signal and the write polarity signal are different, the memory cell 320 may have a low voltage value.

As illustrated in FIG. 5, the threshold voltage (Vth, threshold switching voltage) may be a voltage state at which the coincidence between the read polarity signal and the write polarity signal occurs. The threshold voltage may be a voltage at which the single selection device memory is turned on.

State I may be a set state. The single selection memory may write data in the same direction as the previous state in the set state. The set state may have a low voltage.

State II may be a reset state. The single selection memory may write data in a direction opposite to the previous state in the reset state. The reset state may have a high voltage.

State III may be a read state. The read state may be when a voltage between the set state and the reset state is applied. When the single selection memory is turned on in the read state, the single selection memory may be recognized as the set state. When the single selection memory is turned off in the read state, the single selection memory may be recognized as the reset state.

State IV may be a hold state. The hold state may be a minimum voltage and current condition for maintaining the switch in an on state.

States V, VI, and VII may represent states in which a signal input in the same direction as the read polarity signal generates the set state, and a signal input in the opposite direction to the read polarity signal generates the reset state, when the read polarity signal is defined as a positive signal.

As described above, the weight storage layer 300 may perform artificial neural network (ANN) technology through the plurality of memory cells 320. The weight storage layer 300 may store the weights through the plurality of memory cells 320. The weight storage layer 300 and the logic core layer 100 may be electrically connected to each other through the redistribution wirings 220 of the redistribution wiring layer 200. The weight storage layer 300 and the logic core layer 100 may have the monolithic structure through the redistribution wiring layer 200.

Since the weight storage layer 300 and the logic core layer 100 are electrically connected through the redistribution wiring layer 200, the logic core layer 100 may receive the weights stored in the plurality of memory cells 320 of the weight storage layer 300 by using a small amount of energy. The weights may not need to be learned through feedback, and the weight storage layer 300 may have an optimization structure for obtaining the inference value. The weight storage layer 300 and the logic core layer 100 may be optimized for the inference to obtain the inference value and may have high energy efficiency.

The foregoing is illustrative of example embodiments and is not to be construed as limiting thereof. Although example embodiments have been described, those skilled in the art will readily appreciate that many modifications are possible without materially departing from the novel teachings and advantages of the present invention. Accordingly, all such modifications are intended to be included within the spirit and scope of example embodiments as recited in the claims.

What is claimed is:

1. A semiconductor chip, comprising:
a logic core layer that receives input data and calculates an inference value based on the input data;
a redistribution wiring layer provided on the logic core layer, wherein the redistribution wiring layer includes a plurality of redistribution wirings, which are configured to transmit the input data, and an insulating layer, which covers the plurality of redistribution wirings; and
a weight storage layer provided on the redistribution wiring layer, wherein the weight storage layer includes a plurality of memory cells that are each configured for storing weights for calculating an inference value, wherein the weights are transmitted to the logic core layer through the plurality of redistribution wirings according to the input data.

2. The semiconductor chip of claim 1, wherein the logic core layer includes Static Random Access Memory (SRAM).

3. The semiconductor chip of claim 1, wherein the weight storage layer includes a single select device memory.

4. The semiconductor chip of claim 1, wherein energy generated in data movement between the logic core layer and the weight storage layer is within a range of about 1 Pj/bit to about 3 Pj/bit.

5. The semiconductor chip of claim 1, wherein the plurality of memory cells store the weights by changing voltages within the amorphous materials through read polarity signals and write polarity signals.

6. The semiconductor chip of claim 1, wherein the amorphous materials include at least one of sulfur (S), selenium (Se), tellurium (Te), germanium (Ge), arsenic (As), aluminum (Al), antimony (Sb), and indium (In), gallium (Ga), tin (Sn), bismuth (Bi), palladium (Pd), cobalt (Co), oxygen (O), silver (Ag), gold (Au), nickel (Ni) or platinum (Pt).

7. The semiconductor chip of claim 1, wherein the logic core layer includes first bit line decoders, first word line decoders, and first sense amplifiers for a logic processing unit, and second word line decoders, a second bit line decoder and a second sense amplifier for the plurality of memory cells.

8. The semiconductor chip of claim 7, wherein the first bit line decoders, the first word line decoders, the second bit line decoders and the second sense amplifier form a symmetrical structure with the second word line decoder as the center.

9. The semiconductor chip of claim 1, wherein the insulating layer is bonded to an upper surface of the logic core layer and a lower surface of the weight storage layer, respectively.

10. The semiconductor chip of claim 1, wherein the plurality of redistribution wirings include at least one of copper (Cu), aluminum (Al), tungsten (W), nickel (Ni), molybdenum (Mo), gold (Au), silver (Ag), chromium (Cr), tin (Sn), or titanium (Ti).

11. A semiconductor chip, comprising:
a logic core layer that receives input data and calculates an inference value based on the input data and weights;
a redistribution wiring layer bonded to a surface of the logic core layer, wherein the redistribution wiring layer includes a plurality of redistribution wirings, which are configured to transmit the input data and the weights, and an insulating layer, which covers the plurality of redistribution wirings; and
a weight storage layer provided on the redistribution wiring layer, wherein the weight storage layer includes memory cells that respectively store the weights through amorphous materials, wherein the weight storage is configured to receive the input data through the plurality of redistribution wirings, and transfer at least portions of the weights to the logic core layer through the plurality of redistribution wirings in response to the input data.

12. The semiconductor chip of claim 11, wherein the weight storage layer includes a single select device memory.

13. The semiconductor chip of claim 11, wherein energy generated in data movement between the logic core layer and the weight storage layer is within a range of about 1 Pj/bit to about 3 Pj/bit.

14. The semiconductor chip of claim 11, wherein the memory cells store the weights by changing voltage within the amorphous materials through read polarity signals and write polarity signals.

15. The semiconductor chip of claim 11, wherein the amorphous materials include at least one of sulfur (S), selenium (Se), tellurium (Te), germanium (Ge), arsenic (As), aluminum (Al), antimony (Sb), and indium (In), gallium (Ga), tin (Sn), bismuth (Bi), palladium (Pd), cobalt (Co), oxygen (O), silver (Ag), gold (Au), nickel (Ni) or platinum (Pt).

16. The semiconductor chip of claim 11, wherein the logic core layer includes first bit line decoders, first word line decoders, and first sense amplifiers for a logic processing unit, and second word line decoders, a second bit line decoder and a second sense amplifier for the memory cells.

17. The semiconductor chip of claim 16, wherein the first bit line decoders, the first word line decoders, the second bit line decoders and the second sense amplifiers form a symmetrical structure with the second word line decoder as the center.

18. The semiconductor chip of claim 11, wherein the insulating layer is bonded to an upper surface of the logic core layer and a lower surface of the weight storage layer, respectively.

19. The semiconductor chip of claim 11, wherein the plurality of redistribution wirings include at least one of copper (Cu), aluminum (Al), tungsten (W), nickel (Ni), molybdenum (Mo), gold (Au), silver (Ag), chromium (Cr), tin (Sn) or titanium (Ti).

20. A semiconductor package, comprising:
a package substrate; and
a semiconductor chip disposed on the package substrate,
wherein the semiconductor chip includes:
a logic core layer configured to receive input data through the package substrate, and calculate an inference value based on the input data and weights;
a redistribution wiring layer provided on the logic core layer, wherein the redistribution wiring layer includes a plurality of redistribution wirings, which are configured to transmit the input data and the weights, and an insulating layer, which covers the plurality of redistribution wirings; and
a weight storage layer provided on the redistribution wiring layer, wherein the weight storage layer includes memory cells that respectively store the weights through amorphous materials, wherein the weight storage layer is configured to receive the input data through the plurality of redistribution wirings, and transfer at least portions of the weights to the logic core layer through the plurality of redistribution wirings in response to the input data.
